(19) United States
(12) Patent Application Publication
(10) Pub. No.: US 2023/0195363 A1
(43) Pub. Date: Jun. 22, 2023

(54) NEUROMORPHIC SEMICONDUCTOR DEVICES AND OPERATING METHODS

(71) Applicant: POSTECH Research and Business Development Foundation, Pohang-si (KR)

(72) Inventors: Seyoung KIM, Pohang-si (KR); Kyungmi NOH, Pohang-si (KR); Chaeun LEE, Seoul (KR); Wonjae JI, Pohang-si (KR)

(73) Assignee: POSTECH Research and Business Development Foundation, Pohang-si (KR)

(21) Appl. No.: 17/837,006

(22) Filed: Jun. 9, 2022

(30) Foreign Application Priority Data
Dec. 21, 2021 (KR) 10-2021-0183551

(51) Int. Cl. G06F 3/06; G06N 3/063

(52) U.S. Cl. CPC G06F 3/0655; G06N 3/063; G06F 3/0604; G06F 3/0673

(57) ABSTRACT

According to an embodiment of the present disclosure, a neuromorphic semiconductor device includes a first synaptic array that includes a first synaptic device having a first weight, a second synaptic array that includes a second synaptic device configured to symmetrically adjust a second weight with respect to a potentiation or depression operation, and a control unit that configures a single synapse through the first synaptic device and the second synaptic device and determines a final weight by accessing the first and second weights together in a reading process.

### CROSS REFERENCE TO PRIOR APPLICATIONS

This application claims priority to and the benefit Korean Patent Application No. 10-2021-0183551 filed on Dec. 21, 2021, which is hereby incorporated by reference in their entirety.

### BACKGROUND

The present disclosure relates to neuromorphic semiconductor devices and operating methods, and more particularly, to neuromorphic semiconductor devices to which synaptic devices having different asymmetric update characteristics are applied when configuring cross-point arrays of memory devices and synaptic device arrays, in particular, synaptic devices for vector-matrix operations, weight storage, and the like that are performed during neural network learning.

Recently, research on neuromorphic devices in which a neural network is implemented in hardware has been conducted in various directions. The neuromorphic devices imitate structures of neurons and synapses constituting a brain nervous system of a living body, and generally have structures of pre neurons located before synapses and post neurons located after synapses. A synapse is a connection point between neurons, and has a function of updating and memorizing a synaptic weight according to a spike signal generated from both neurons.

In general, upon learning a neural network using a synaptic device array, it is important to update correct weights on a synaptic device in order to improve learning performance. Therefore, in one update, a conductance value updated in the synaptic device needs to match a target value. However, in the case where synaptic devices, such as resistive RAM (ReRAM), phase change memory (PCM), ferroelectric RAM (FeRAM), and electrochemical RAM (ECRAM), are being actively studied, even with the same conductance value, the amount of conductance updated at one time varies depending on a direction of increase or decrease in conductance. This is called an asymmetric update characteristic of the device, and the asymmetric update characteristic prevents accurate weight values from being memorized in the device, which becomes a major cause of deterioration in the neural network learning performance. However, since this is physical characteristics according to the structure of the synaptic device and the resulting conductance change mechanism, research to improve the update asymmetry of the device is continuing.

Korean Patent Laid-Open Publication No. 10-2020-0100286 describes a neuromorphic circuit system capable of efficiently implementing a negative weight, in which the circuit system includes a plurality of pre neurons, a plurality of post neurons, and a plurality of row lines extending in a row direction from each of the pre neurons, a plurality of synapses that are disposed on intersections of a plurality of column lines corresponding to each of the post neurons to form a synaptic array, a shift circuit that adds and sums a shift weight to inputs of the plurality of pre neurons and outputs the summed result, and a subtraction circuit that subtracts an output of the shift circuit from outputs of each of the plurality of column lines and outputs the subtracted output to each of the post neurons, and each of the plurality of synapses has a weight shifted from an original weight to the shift weight.

### RELATED ART DOCUMENT

### Patent Document

Korean Patent Laid-Open Publication No. 10-2020-0100286 (Aug. 26, 2020)

### SUMMARY

The present disclosure provides neuromorphic semiconductor devices and operating methods capable of implementing an analog neural network accelerator and ensuring high neural network learning performance by applying a synaptic device having different asymmetric update characteristics when configuring a cross-point array of the synaptic device for operation, weight storage, etc., to alleviate asymmetry conditions that are difficult to improve due to physical limitations of the existing synaptic device.

An exemplary embodiment of the present disclosure provides a neuromorphic semiconductor device including: a first synaptic array that includes a first synaptic device having a first weight; a second synaptic array that includes a second synaptic device configured to symmetrically adjust a second weight with respect to a potentiation or depression operation; and a control unit that configures a single synapse through the first synaptic device and the second synaptic device and determines a final weight by accessing the first and second weights together in a reading process.

The first synaptic array and the second synaptic array may be configured of any one selected from resistive RAM (ReRAM), phase change memory (PCM), ferroelectric RAM (FeRAM), and electrochemical RAM (ECRAM) as a synaptic device.

The first synaptic array and the second synaptic array may use a synaptic device having different update asymmetry.

The first synaptic array and the second synaptic array may use different synaptic devices, and the second synaptic device may configure a neural network using a synaptic device having relatively small update asymmetry compared to the first synaptic device.

The first synaptic array and the second synaptic array may use the same synaptic device, and the second synaptic device may configure a neural network by adjusting relatively small update asymmetry compared to the first synaptic device.

The final weight determined by the control unit may be calculated as in Equation 1 below.

W=γW_{A}+W_{C} [Equation 1]

The control unit may compare an output value with a value to be predicted based on an operation of propagating an output value for each input value and an error between an ideal value and an actual value to an opposite side of an output layer to calculate an error value using a current input value and a memorized weight, and the calculated error value may be calculated as in Equation 2 below.

y=Wx_{idc} [Equation 2]

The control unit may calculate an optimal combination of the update asymmetric characteristics of the first synaptic device and the second synaptic device in a learning rate space based on a robustness score RS(m), and the robustness score RS(m) may be the same as in [Equation 3] below.

$$RS ( m ) = {\sum }_{h ∈ ℋ} 1 ( Meas ( m ( h ) ) > th ) \qquad [ Equation 3 ]$$

Another exemplary embodiment of the present disclosure provides an operating method of a neuromorphic semiconductor device that includes a first synaptic array including a first synaptic device having a first weight and a second synaptic device configured to symmetrically adjust a second weight with respect to a potentiation or depression operation and having a different update asymmetry from the first synaptic device, the operating method including: summing values of the first weight and the second weight at a specific ratio and storing the summed value as a weight of a neural network; calculating an update amount through an error backpropagation method from the weight; performing weight update on the first synaptic array; and updating the weight input to the first synaptic device of the first synaptic array to the second synaptic device of the second synaptic array at the same location.

The first synaptic array and the second synaptic array may be configured of any one selected from resistive RAM (ReRAM), phase change memory (PCM), ferroelectric RAM (FeRAM), and electrochemical RAM (ECRAM) as a synaptic device.

The first synaptic device may have relatively large update asymmetry compared to the second synaptic device, and the second synaptic device may have relatively small update asymmetry compared to the first synaptic device.

The weight of the neural network may use a linearly combined value of a weight W^{A} memorized in a first synaptic device of the first synaptic array and a weight W^{C} memorized in a second synaptic device of the second synaptic array at the same location as the first synaptic device of the first synaptic array.

The weight memorized in the first synaptic array A may be read every specific period, and the weight input to the first synaptic device of the first synaptic array may be updated to the second synaptic device of the second synaptic array at the same location.

### BRIEF DESCRIPTION OF THE DRAWINGS

FIG. 1 is a diagram illustrating a fully connected layer neural network.

FIG. 2 is a diagram illustrating a synaptic array to which a neural network may be applied.

FIGS. 3A and 3B are diagrams illustrating a response graph to an update input of a synaptic device.

FIG. 4 is a diagram simply illustrating a state in which an algorithm according to an embodiment of the present disclosure is implemented as a synaptic array.

FIGS. 5A and 5B are graphs illustrating a response to an update input of each synaptic array.

FIG. 6 is a flowchart for describing a method of updating weights in two synaptic arrays of FIG. 4.

FIGS. 7A and 7B are diagrams illustrating experimental data for describing an effect of an update asymmetric characteristic of a synaptic array on a neural network.

FIG. 8 is a diagram data showing robustness score RS(m) for learning.

FIG. 9 is a diagram illustrating a neural network learning result using a synaptic device having different update asymmetry as in FIG. 4.

FIG. 10 is a diagram illustrating a response graph of a synaptic device having update asymmetry corresponding to part ‘A’ of FIG. 9.

### DETAILED DESCRIPTION

Since the description of the present disclosure is merely an embodiment for structural or functional explanation, the scope of the present disclosure should not be construed as being limited by the embodiments described in the text. That is, since the embodiments may be variously modified and may have various forms, the scope of the present disclosure should be construed as including equivalents capable of realizing the technical idea. In addition, a specific embodiment is not construed as including all the objects or effects presented in the present disclosure or only the effects, and therefore the scope of the present disclosure should not be understood as being limited thereto.

On the other hand, the meaning of the terms described in the present application should be understood as follows.

Terms such as “first” and “second” are intended to distinguish one component from another component, and the scope of the present disclosure should not be limited by these terms. For example, a first component may be named a second component and the second component may also be similarly named the first component.

It is to be understood that when one element is referred to as being “connected to” another element, it may be connected directly to or coupled directly to another element or be connected to another element, having the other element intervening therebetween. On the other hand, it is to be understood that when one element is referred to as being “connected directly to” another element, it may be connected to or coupled to another element without the other element intervening therebetween. In addition, other expressions describing a relationship between components, that is, “between”, “—directly between”, “—neighboring to”, “directly neighboring to” and the like, should be similarly interpreted.

It should be understood that the singular expression include the plural expression unless the context clearly indicates otherwise, and it will be further understood that the terms “comprises” or “have” used in this specification, specify the presence of stated features, steps, operations, components, parts, or a combination thereof, but do not preclude the presence or addition of one or more other features, numerals, steps, operations, components, parts, or a combination thereof.

In each step, an identification code (for example, a, b, c, and the like) is used for convenience of description, and the identification code does not describe the order of each step, and each step may be different from the specified order unless the context clearly indicates a particular order. That is, the respective steps may be performed in the same sequence as the described sequence, be performed at substantially the same time, or be performed in an opposite sequence to the described sequence.

The present disclosure can be embodied as computer readable code on a computer readable recording medium, and the computer readable recording medium includes all types of recording devices in which data can be read by a computer system. Examples of the computer readable recording medium may include a read only memory (ROM), a random access memory (RAM), a compact disk read only memory (CD-ROM), a magnetic tape, a floppy disk, an optical data storage, or the like. In addition, the computer readable recording medium may be distributed in computer systems connected to each other through a network, such that the computer readable codes may be stored in a distributed scheme and executed.

Unless defined otherwise, all the terms used herein including technical and scientific terms have the same meaning as meanings generally understood by those skilled in the art to which the present disclosure pertains. It should be understood that the terms defined by the dictionary are identical with the meanings within the context of the related art, and they should not be ideally or excessively formally defined unless the context clearly dictates otherwise.

Hereinafter, preferred embodiments of the present disclosure will be described in more detail with reference to the drawings. Hereinafter, the same components will be denoted by the same reference numerals throughout the drawings, and an overlapping description for the same components will be omitted.

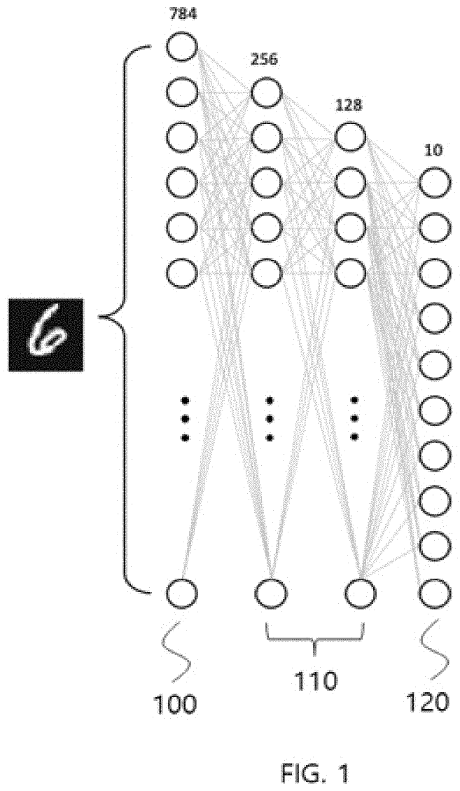

FIG. 1 is a diagram illustrating a fully connected layer neural network.

Referring to FIG. 1, a unit in which several neurons are gathered is called a layer, and a fully connected layer is a structure in which all cases of each layer are connected. When neurons of an input layer and neurons of an output layer are connected equal to the number of all possible connections, it is called a fully connected layer. Such a neural network includes an input layer 100, a hidden layer 110, and an output layer 120.

The input layer receives the input and passes the received input to the next layer, the hidden layer, and the hidden layer is a fully coupled layer connected to the input layer, which may be a core layer that may solve complex problems. Finally, the output layer is a fully coupled layer following the hidden layer, and is used to transmit an output signal to the outside of the neural network, and a function of the neural network is determined by an activation function of the output layer.

Here, a two-stage fully connected layer neural network that performs an operation of classifying a modified national institute standards and Technology) is illustrated. For example, when data used is composed of a total of 784 pixels, an input node is also composed of 784.

In addition, the total number of output nodes is 10 because the number between 0 and 9 needs to be distinguished as an output. Here, two hidden layers are illustrated, and 256 nodes are set in a first hidden layer and 128 nodes are set in a second hidden layer, but the number of nodes constituting the hidden layer is not limited thereto. The learning process includes a forward pass and a backward pass, and then weights are updated. In this case, the matrix operation occupies the greatest proportion.

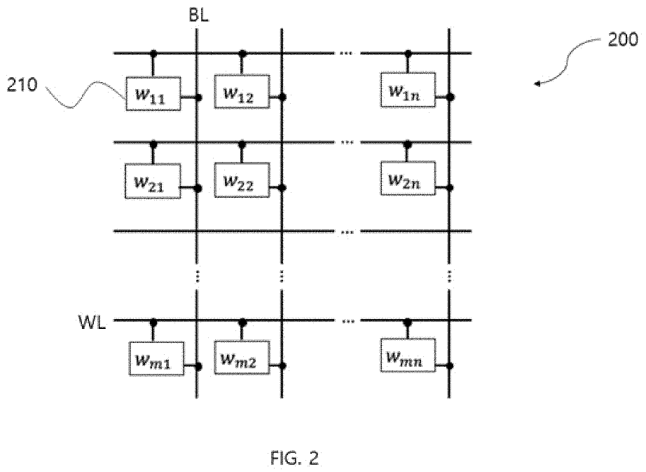

FIG. 2 is a diagram illustrating a synaptic array to which a neural network may be applied.

A synaptic array 200 of FIG. 2 represents an m×n array using a synaptic device in an analog hardware accelerator, and includes a plurality of bit lines BL extending in a first direction, and a plurality of word lines WL extending in a second direction perpendicular to the first direction. A synaptic device 210 is located in each region where the bit line and the word line intersect. A neural network device configured of such an array has a high proportion of a matrix operation, and may substitute values of each element of the matrix of the operation with the conductivity of each memory element and calculate a matrix product by giving a voltage pulse and integrating a flowing current. In this case, the conductance value memorized in each synaptic device is used as a weight in the neural network, and as the weight is accurately recorded, a neural network having excellent learning performance characteristics may be provided.

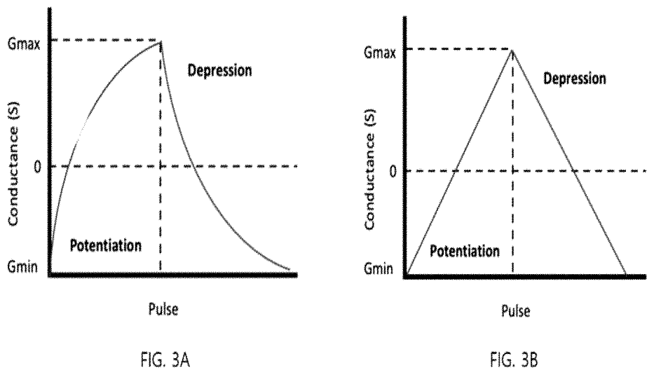

The update characteristics of the synaptic device will be described below with reference to FIGS. 3A and 3B.

FIGS. 3A and 3B are graphs showing a response to an update input of a synaptic device, and is a graph showing a change in a conductance value according to a change in a pulse applied to the synaptic device.

First, FIG. 3A illustrates a graph of a response of a device having asymmetric update characteristic, and it can be seen that a slope when a potentiation operation occurs and a slope when a depression operation occurs are different for one conductance value.

Meanwhile, FIG. 3B illustrates a response graph of a device having symmetric update characteristic, and it can be seen that the slope when the potentiation operation occurs and the slope when the depression operation occurs are the same for all conductance values.

As described in FIGS. 3A and 3B, each synaptic device has different asymmetric update characteristics, and the present disclosure intends to configure a synaptic array using synaptic devices having different asymmetric update characteristics.

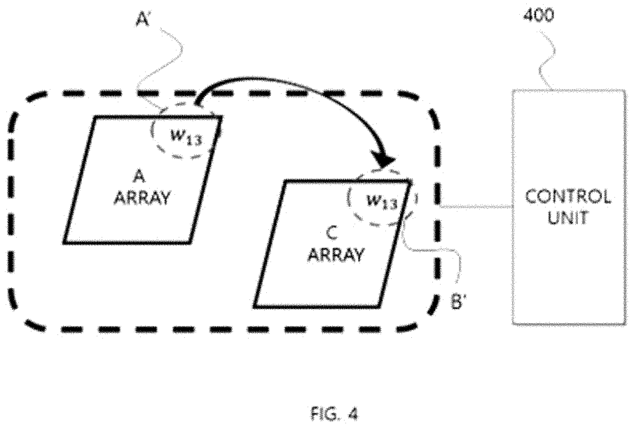

FIG. 4 is a diagram simply illustrating a state in which an algorithm according to an embodiment of the present disclosure is implemented as a synaptic array.

From a software point of view, the Tiki-Taka algorithm was proposed to improve the learning performance degradation problem caused by the update asymmetry of the device. The algorithm is an improvement of the existing gradient descent algorithm, and a neural network is learned using two synaptic device arrays (first synaptic array A and second synaptic array C). Here, the first synaptic array A includes a first synaptic device A′ having a first weight, and the second synaptic array C includes a second synaptic device C′ configured to symmetrically adjust the second weight with respect to the potentiation or depression operation, a single synapse is formed through the first synaptic device and the second synaptic device, and the neural network includes a control unit 400 that determines a final weight by accessing the first and second weights together during the reading process.

That is, the synaptic device having different update asymmetry is used for the first synaptic array A and the second synaptic array C.

In this case, the synaptic device of the first synaptic array A and the second synaptic array C may use any one selected from resistive RAM (ReRAM), phase change memory (PCM), ferroelectric RAM (FeRAM), and electrochemical RAM (ECRAM), and it is preferable that the second synaptic device C′ of the second synaptic array (C) uses a device having a smaller update asymmetry compared to the first synaptic device A′ of the first synaptic array A.

For example, the first synaptic array A and the second synaptic array B use the same synaptic device, but the first synaptic device of the first synaptic array A may be adjusted to have a larger device update asymmetry than the second synaptic device of the second synaptic array B.

In addition, the first synaptic array A and the second synaptic array B use different synaptic devices, but the neural network may be configured by using a synaptic device having a relatively large device update asymmetry in the first synaptic array A and using a synaptic device having a small device update asymmetry in the second synaptic array C.

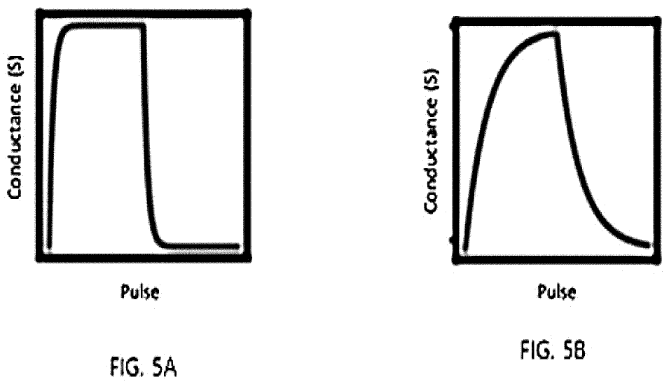

Referring to FIGS. 5A and 5B, the response graph to the update input of each synaptic array is as follows. First, the first synaptic array A using a synaptic device having relatively large asymmetry may represent a reaction graph as illustrated in FIG. 5A, and the second synaptic array C using a synaptic device having relatively small asymmetry may represent a reaction graph as in FIG. 5B.

As such, when a relatively symmetric update is performed on the second synaptic device C′ of the second synaptic array C, even if the first synaptic device A′ of the first synaptic array A uses 7 to 10 times more asymmetric update characteristics, it is possible to ensure excellent neural network learning performance.

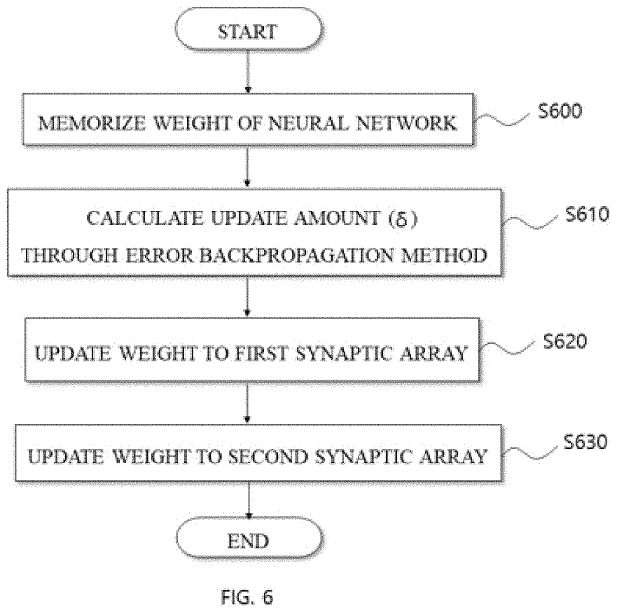

FIG. 6 is a flowchart for describing a method of updating weights in two synaptic arrays of FIG. 4.

Referring to FIG. 6, the weights of the neural network are memorized by adding the weights stored in the first synaptic array A and the second synaptic array C at a specific ratio (step S600).

More specifically, the total weight W may use a linearly combined value of a weight W^{A} memorized in the first synaptic device of the first synaptic array A and a weight W^{C} memorized in the second synaptic device of the second synaptic array C at the same location as the first synaptic device of the first synaptic array A. This may be expressed as Equation 1 below.

W=γW^{A}+W^{C} [Equation 1]

Next, an update amount δ is calculated from this weight by an error backpropagation method (step S610). In this case, in the synaptic device, the connection and the connection strength, i.e., the weight, of nodes of various layers may be obtained through the learning process, and the back propagation method refers to the process of changing the weight by comparing the output value with the actually predicted value based on the operation of propagating the output value for each input value, and the error between the ideal value and the actual value to the opposite side of the output layer. This may be expressed as Equation 2 below.

y=Wx_{idx} [Equation 2]

Thereafter, the weight update is performed on the first synaptic array (step S620).

Then, the weights memorized in the first synaptic array A are read at every specific period, and the first synaptic array A compares the weights input to the first synaptic device to the second synaptic device of the second synaptic array C at the same location (step S620). In this case, the update process may be performed according to a transfer learning rate. Here, the transfer learning rate means a rate of transferring a weight from the first synaptic array A to the second synaptic array C.

The algorithm renews the update asymmetry of the device by using the two synaptic arrays, and shows a learning result (MNIST pattern recognition result, ˜98%) that is close to the neural network learning result using digital hardware. That is, the high learning performance may be ensured despite the asymmetric update of the synaptic device.

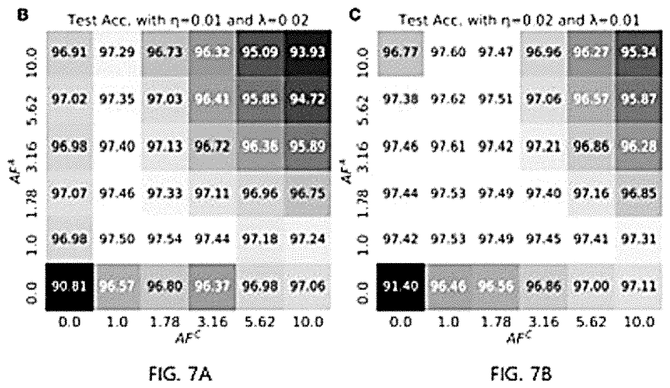

FIGS. 7A and 7B illustrate experimental data for describing an effect of the update asymmetric characteristic of the synaptic array on the neural network.

FIGS. 7A and 7B illustrate experimental data on an effect of the update asymmetric feature AF^{A} of the first synaptic array and an update asymmetric feature AF^{C} of the second synaptic array on neural network learning. Here, FIGS. 7A and 7B illustrate the results of testing the accuracy of a multilayer perceptron as a function of AF^{A} and AF^{C} values, and the results using two sets of stochastic gradient descent (SGD) and transfer leaning rate. The optimal combination of the AF values that give the best accuracy may be changed when learning speed combinations vary.

For example, in FIG. 7A, the accuracy of the test is highest a combination of (AF^{A}, AF^{C}) ∈{(1.0, 1.0), (1.78, 1.0), (1.0, 1.78)} when a transfer learning rate η and an SGD learning rate λ are (0.01, 0.02).

However, as can be seen from FIG. 7B, the AF combination appears optimally in the following cases. When the neural network of (AF^{A}, AF^{C})∈{(3.16, 1.0), (5.62, 1.0), (10.0, 1.0)} is learned at different learning rates, it is important to find robust AF^{A} and AF^{C} values in a learning rate space in which the accuracy is not reduced.

From the point of view, it is possible to find the optimal combination of AF in the learning rate space through the robustness score without searching for the best learning rate pair by introducing a threshold value for a certain measurement value such as the test accuracy. This robustness score RS(m) may be calculated as in [Equation 3] below.

$$RS ( m ) = {\sum }_{h ∈ ℋ} 1 ( Meas ( m ( h ) ) > th ) \qquad [ Equation 3 ]$$

Here, m is a neural network model, and Meas is a measurement value such as accuracy or loss of the neural network model after learning on a given data set.

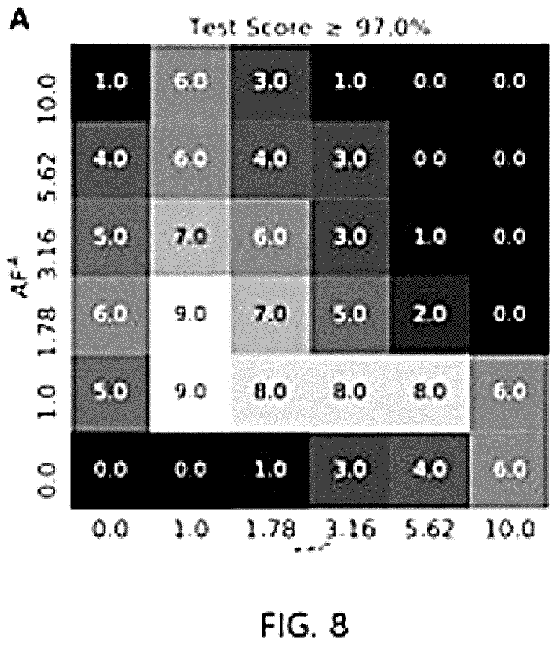

FIG. 8 illustrates H={(η,λ)} as data showing the robustness score RS(m) for learning, where FIG. 8 illustrates the robustness score when η∈{0.01, 0.02, 0.04} and λ∈{0.01, 0.02, 0.04}. The robustness score showed that the update asymmetric characteristics of each array affect the test accuracy of the network using the Tiki Taka algorithm, and when the update asymmetric characteristics of each array are too small (AF^{A}, AF^{C}=0) or too large (AF^{A}, AF^{C}=10), the test accuracy does not reach sufficient values.

Therefore, the optimal AF value pair that maximizes the robustness score exists near AF^{A}, AF^{C}=1, as illustrated in FIG. 8. Once the minimum requirements for the test accuracy (threshold) have been determined, a minimum specification for the update asymmetry may be defined using regions where the robustness score is above a certain criterion, and a range of the AF values may be obtained for each array that ensures minimum test accuracy.

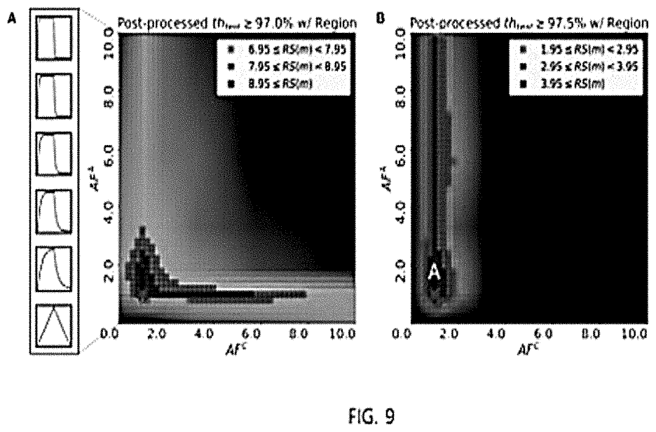

Additionally, various learning rate pairs may be scanned to identify regions that provide AF values. In order to find these regions, the learning rate of the neural network is changed and the MNIST pattern recognition task is learned with a two-stage fully connected layer neural network, and the case in which the learning performance data so obtained shows an abnormality in characteristic performance may be shown by post-processing with Gaussian filtering and interpolation (see FIG. 9).

FIG. 9 illustrates a neural network learning result using a synaptic device having different update asymmetry as in FIG. 4, where an X-axis represents the update asymmetry AF^{C} of the second synaptic device, and a Y-axis represents the update asymmetry AF^{A} of the first synaptic device. Here, the larger the number, the greater the update asymmetry.

The interpolated data of the AF^{A} and AF^{C} regions may be obtained by Gaussian filtering (g(AF^{A},AF^{C})), and may be calculated as shown in [Equation 4] below.

g(AF^{A},AF^{C})=(2πσ2)−½·exp(−((AF^{A})²+(AF^{C})2)/(2σ2)) [Equation 4]

Here, it is possible to define the degree of “robustness” of the score map by modulating the σ of the Gaussian filter. In FIG. 9, the strong regions are around AF^{A}=1.2 and AF^{C}=1.0, in which the score is higher than 8.95, and regions with high scores above 8.95 may indicate the required test accuracy within the given range. Compared to the region in the range of the learning rate pair, the region with RS(m)=4.5 and RS(m)≥8.95 show almost doubling efficiency during the in-device learning. When a hyperparameter space H may be expanded to include, the correction method for finding the best combination of AFs may be also be applied to other types of hyperparameters.

Referring to FIG. 9, when the second synaptic array element performs a relatively small asymmetric update, even if the first synaptic array element has an asymmetric update characteristic of about 10 times or more compared to the second synaptic array element, it can be seen that the learning performance of 97.5% or more is shown.

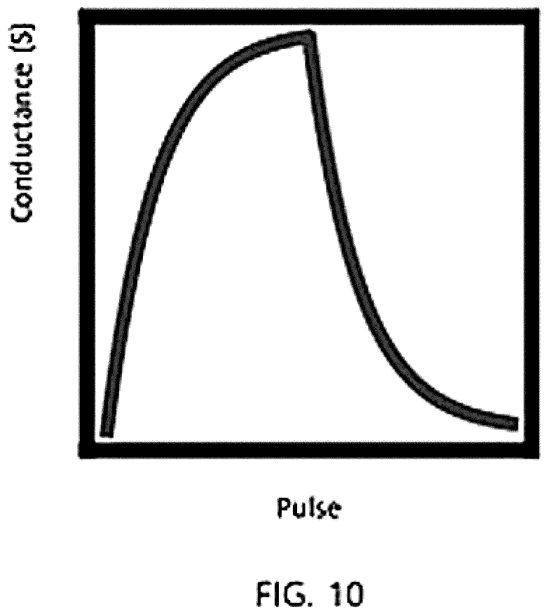

FIG. 10 illustrates a response graph of a synaptic device having update asymmetry corresponding to part ‘A’ of FIG. 9, and it can be seen that FIG. 10 illustrates the update asymmetry of the device whose current weight value is updated in a linearly proportional amount from −1 to 1 for 600 update inputs.

As described above, an embodiment of the present disclosure uses devices with different update asymmetry for each synaptic array to alleviate the conditions of asymmetry which are difficult to improve due to the physical limitations of synaptic devices, thereby helping the implementation of network accelerators, and at the same time ensuring the high neural network learning performance.

The disclosed technology can have the following effects. However, since a specific embodiment is not construed as including all of the following effects or only the following effects, it should not be understood that the scope of the disclosed technology is limited to the specific embodiment.

According to an embodiment of the present disclosure, neuromorphic semiconductor devices and operating methods may implement an analog neural network accelerator and ensure high neural network learning performance by applying a synaptic device having different asymmetric update characteristics when configuring a cross-point array of the synaptic device for operation, weight storage, etc., to alleviate asymmetry conditions that are difficult to improve due to physical limitations of the existing synaptic device.

Although exemplary embodiments of the present disclosure have been disclosed hereinabove, it may be understood by those skilled in the art that the present disclosure may be variously modified and altered without departing from the scope and spirit of the present disclosure described in the following claims.

What is claimed is:

1. A neuromorphic semiconductor device, comprising:
a first synaptic array that includes a first synaptic device having a first weight;
a second synaptic array that includes a second synaptic device configured to symmetrically adjust a second weight with respect to a potentiation or depression operation; and
a control unit that configures a single synapse through the first synaptic device and the second synaptic device and determines a final weight by accessing the first and second weights together in a reading process.

2. The neuromorphic semiconductor device of claim 1, wherein the first synaptic array and the second synaptic array are configured of any one selected from resistive RAM (ReRAM), phase change memory (PCM), ferroelectric RAM (FeRAM), and electrochemical RAM (ECRAM) as a synaptic device.

3. The neuromorphic semiconductor device of claim 1, wherein the first synaptic array and the second synaptic array use a synaptic device having different update asymmetry.

4. The neuromorphic semiconductor device of claim 1, wherein the first synaptic array and the second synaptic array use different synaptic devices, and the second synaptic device configures a neural network using a synaptic device having relatively small update asymmetry compared to the first synaptic device.

5. The neuromorphic semiconductor device of claim 1, wherein the first synaptic array and the second synaptic array use the same synaptic device, and the second synaptic device configures a neural network by adjusting relatively small update asymmetry compared to the first synaptic device.

6. The neuromorphic semiconductor device of claim 1, wherein the final weight determined by the control unit is calculated as in Equation 1 below.
W=γW_{A}+W_{C} [Equation 1]

7. The neuromorphic semiconductor device of claim 1, wherein the control unit compares an output value with a value to be predicted based on an operation of propagating an output value for each input value and an error between an ideal value and an actual value to an opposite side of an output layer to calculate an error value using a current input value and a memorized weight, and the calculated error value is calculated as in Equation 2 below.
y=Wx_{idx} [Equation 2]

8. The neuromorphic semiconductor device of claim 1, wherein the control unit calculates an optimal combination of the update asymmetric characteristics of the first synaptic device and the second synaptic device in a learning rate space based on a robustness score RS(m), and the robustness score RS(m) is the same as in [Equation 3] below.
$$RS ( m ) = {\sum }_{h ∈ ℋ} 1 ( Meas ( m ( h ) ) > th ) \qquad [ Equation 3 ]$$

9. An operating method of a neuromorphic semiconductor device that includes a first synaptic array including a first synaptic device having a first weight and a second synaptic array including a second synaptic device configured to symmetrically adjust a second weight with respect to a potentiation or depression operation and having a different update asymmetry from the first synaptic device, the operating method comprising:
summing values of the first weight and the second weight at a specific ratio and storing the summed value as a weight of a neural network;
calculating an update amount through an error backpropagation method from the weight value;
performing weight update on the first synaptic array; and
updating the weight value input to the first synaptic device of the first synaptic array to the second synaptic device of the second synaptic array at the same location.

10. The neuromorphic semiconductor device of claim 9, wherein the first synaptic array and the second synaptic array are configured of any one selected from resistive RAM (ReRAM), phase change memory (PCM), ferroelectric RAM (FeRAM), and electrochemical RAM (ECRAM) as a synaptic device.

11. The operating method of claim 9, wherein the first synaptic device has relatively large update asymmetry compared to the second synaptic device, and the second synaptic device has relatively small update asymmetry compared to the first synaptic device.

12. The operating method of claim 9, wherein the weight value of the neural network uses a linearly combined value of a weight value W^{A} memorized in a first synaptic device of the first synaptic array and a weight value W^{C} memorized in a second synaptic device of the second synaptic array at the same location as the first synaptic device of the first synaptic array.

13. The operating method of claim 9, wherein the weight value memorized in the first synaptic array A is read every specific period, and the weight value input to the first synaptic device of the first synaptic array is updated to the second synaptic device of the second synaptic array at the same location.
